(19) United States
(12) Patent Application Publication
(10) Pub. No.: US 2011/0170303 A1
(43) Pub. Date: Jul. 14, 2011

(54) CHIP PACKAGE AND FABRICATION METHOD THEREOF

(76) Inventors: Shang-Yi Wu, Hsinchu (TW); Tsang-Yu Liu, Hsinchu (TW)

(21) Appl. No.: 13/005,692

(22) Filed: Jan. 13, 2011

Related U.S. Application Data
(60) Provisional application No. 61/295,029, filed on Jan. 14, 2010.

(51) Int. Cl. F21V 21/002; H05K 7/00; H05K 13/00

(52) U.S. Cl. 362/382; 361/783; 29/825

(57) ABSTRACT

A chip package includes a substrate having an upper, a lower, a first side, and a second side surfaces, a chip having a first and a second electrodes, a first trench extending from the upper surface toward the lower surface and from the first side surface toward an inner portion of the substrate, a first conducting layer overlying a sidewall of the first trench and electrically connecting the first electrode, which is not coplanar with the first side surface and separated from the first side surface by a first distance, a second trench extending from the upper surface toward the lower surface and from the second side surface toward the inner portion, and a second conducting layer overlying a sidewall of the second trench and electrically connecting the second electrode, which is not coplanar with the second side surface and separated from the second side surface by a second distance.

### CROSS REFERENCE

This Application claims the benefit of U.S. Provisional Application No. 61/295,029, filed on Jan. 14, 2010, the entirety of which is incorporated by reference herein.

### BACKGROUND OF THE INVENTION

1. Field of the Invention

The present invention relates to a chip package, and in particular relates to a light emitting chip package.

2. Description of the Related Art

The chip packaging process is as important process when fabrication an electronic product. Chip packages not only provide chips with protection from environmental contaminants, but also provide an interface for connection between electronic elements in the chips and electronic elements outside of the chip package.

Forming a reliable chip package with low cost is an important issue.

### BRIEF SUMMARY OF THE INVENTION

An embodiment of the present invention provides a chip package including a carrier substrate having an upper surface and an opposite lower surface and having a first side surface and a second side surface, a chip disposed on the upper surface of the carrier substrate and having a first electrode and a second electrode, a first trench extending from the upper surface toward the lower surface of the carrier substrate and extending from the first side surface toward an inner portion of the carrier substrate, a first conducting layer located on a sidewall of the first trench and electrically connected to the first electrode, wherein the first conducting layer is not coplanar with the first side surface and is separated from the first side surface by a first minimum distance, a second trench extending from the upper surface toward the lower surface of the carrier substrate and extending from the second side surface toward the inner portion of the carrier substrate, and a second conducting layer located on a sidewall of the second trench and electrically connected to the second electrode, wherein the second conducting layer is not coplanar with the second side surface and is separated from the second side surface by a second minimum distance.

An embodiment of the present invention provides a method for forming a chip package including providing a carrier wafer including a plurality of regions defined by a plurality of predetermined scribe lines, forming a plurality of through-holes penetrating an upper surface and an opposite lower surface of the carrier wafer on locations of the predetermined scribe lines, forming a conducting material layer overlying the carrier wafer, wherein the conducting material layer is extended on sidewalls of the through-holes, patterning the conducting material layer into a plurality of conducting layers which are separated from each other and do not contact with the predetermined scribe lines, providing a plurality of chips each having a first electrode and a second electrode, correspondingly disposing the chips on the regions, wherein at least one of the chips is disposed on each of the regions, and the first electrode and the second electrode of each of the chips are electrically connected to at least two of the conducting layers in the regions where the chips are located, and dicing the carrier wafer along the predetermined scribe lines to separate a plurality of chip packages.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1G are illustrative three-dimensional views showing the steps of forming a chip package according to an embodiment of the present invention;

FIGS. 2A-2E are illustrative cross-sectional views showing the steps of forming the chip package corresponding the embodiment shown in FIG. 1;

FIGS. 3A-3E are illustrative cross-sectional views showing the steps of forming a chip package according to an embodiment of the present invention;

FIGS. 4A-4C are top views showing the steps of forming a patterned conducting layer in a through-hole according to an embodiment of the present invention;

FIGS. 5A and 5B are illustrative three-dimensional views showing chip packages according to embodiments of the present invention;

FIG. 6A is an illustrative three-dimensional view showing a chip package according to an embodiment of the present invention; and

FIG. 6B is an illustrative cross-sectional view showing a chip package according to an embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer include embodiments where the first and second layers are in direct contact and those where one or more layers are interposing the first and second layers.

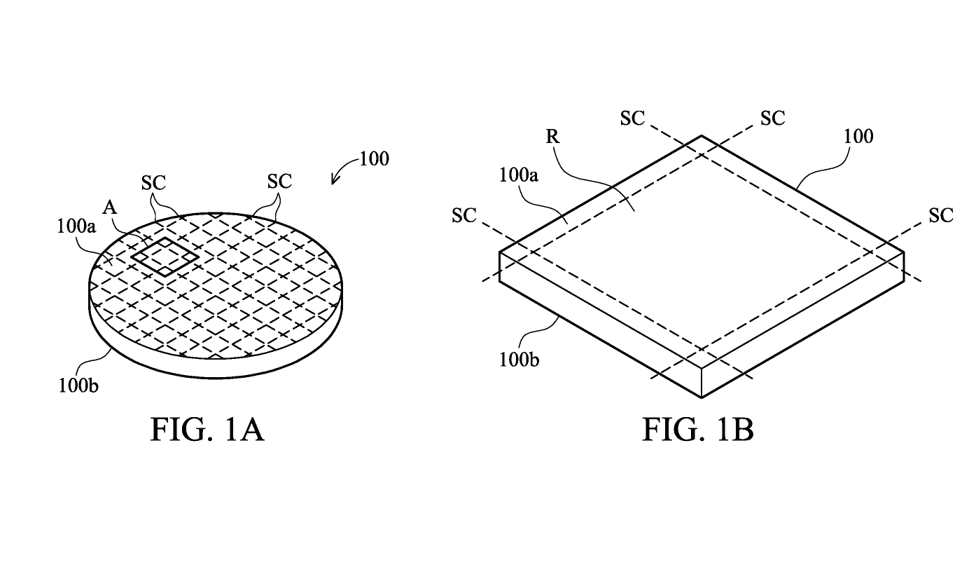

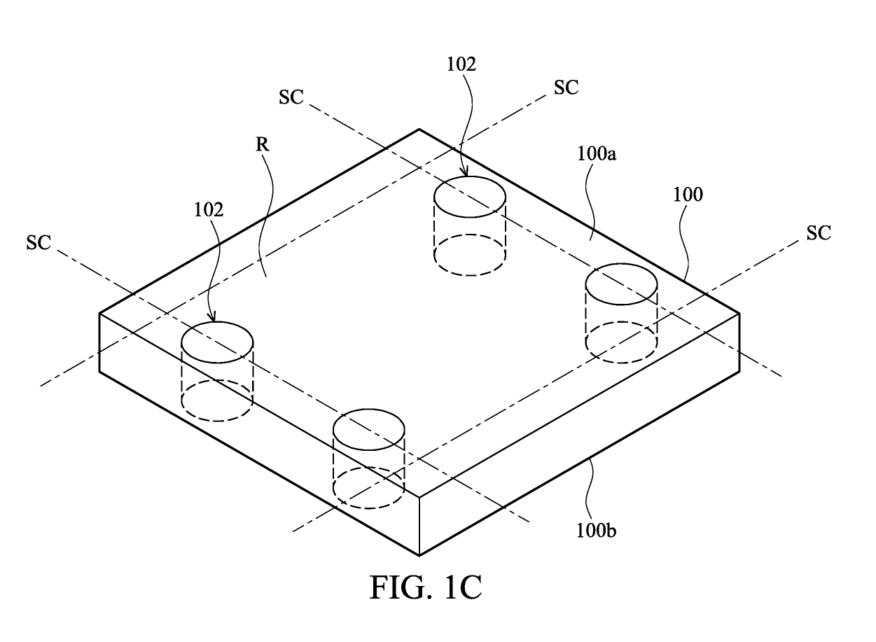

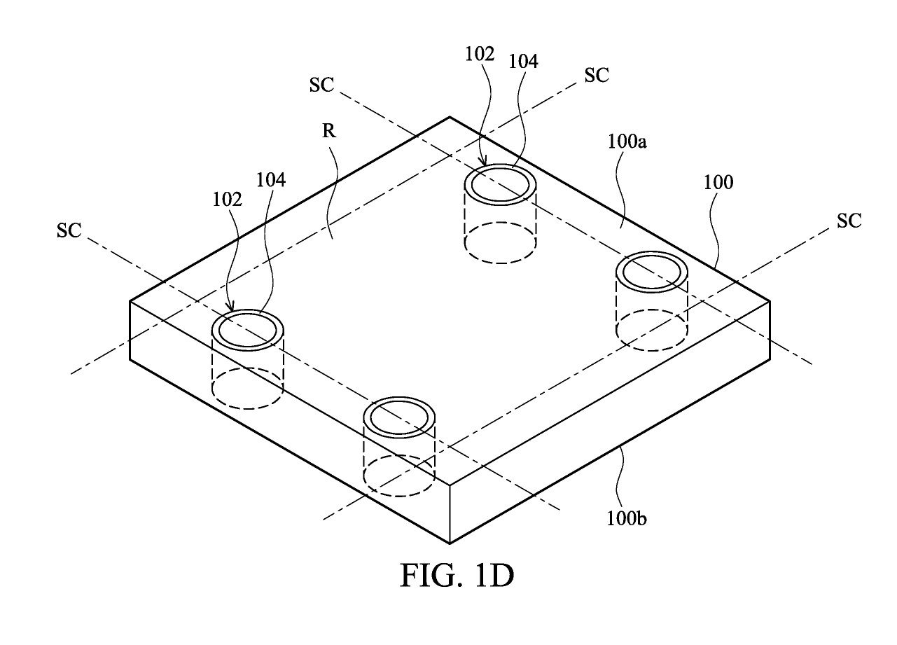

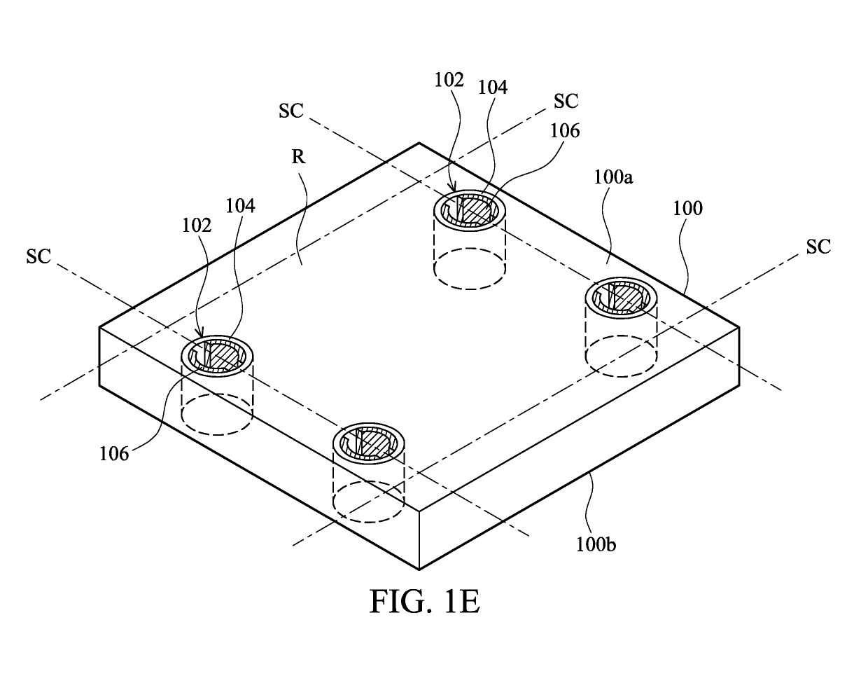

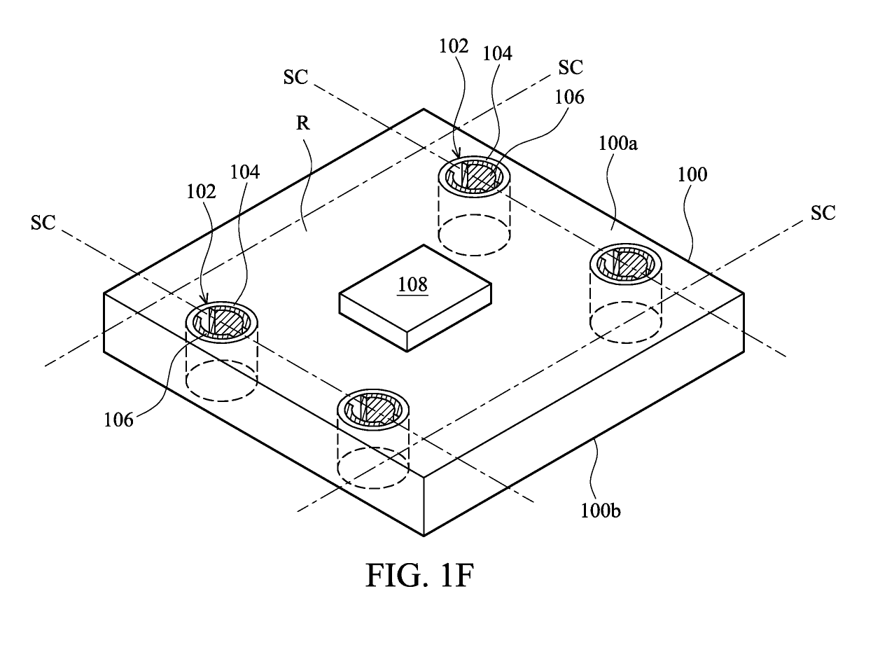

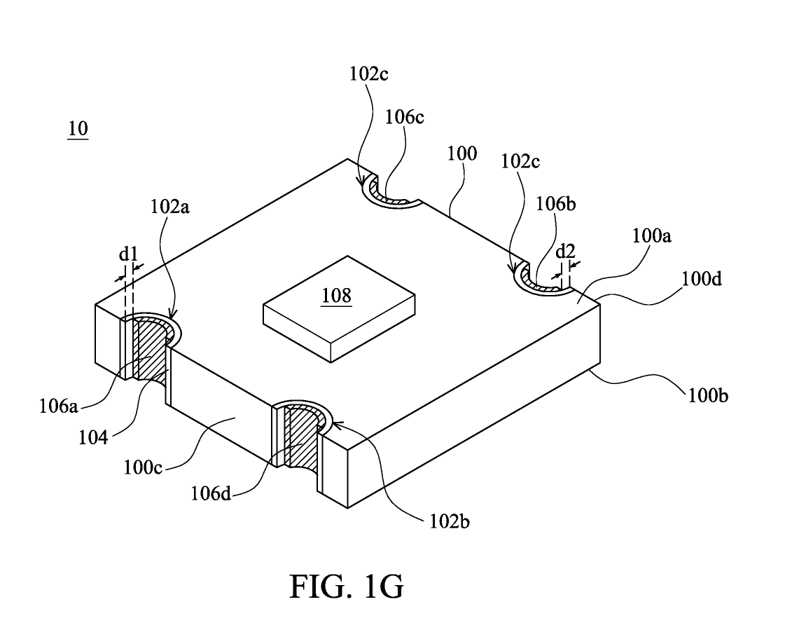

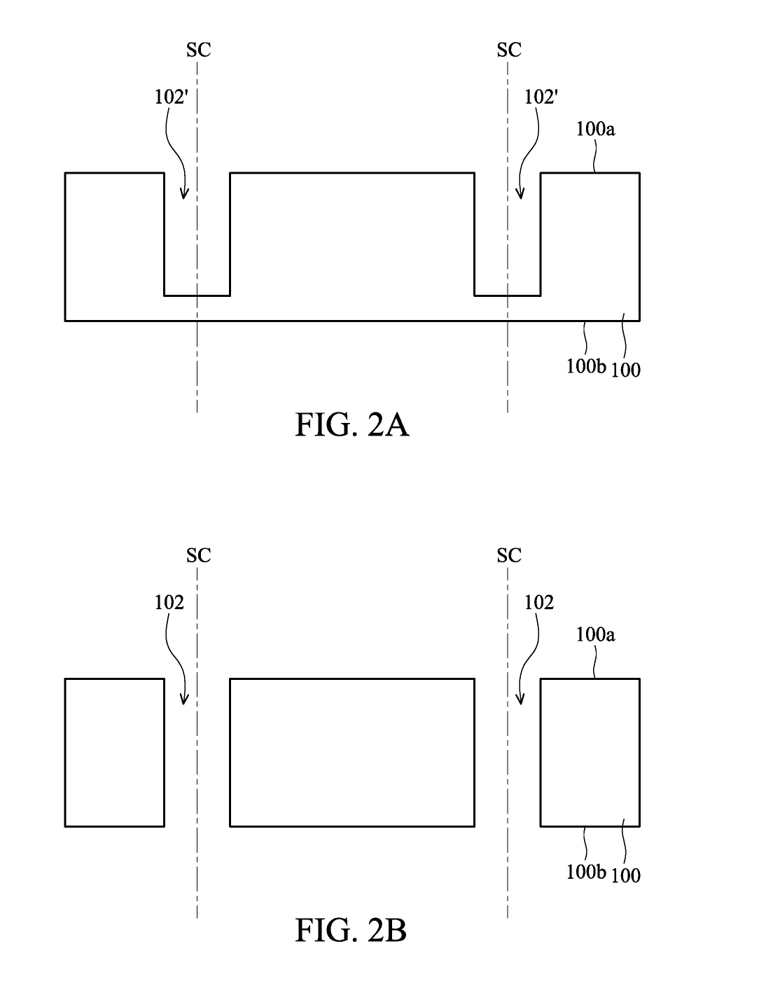

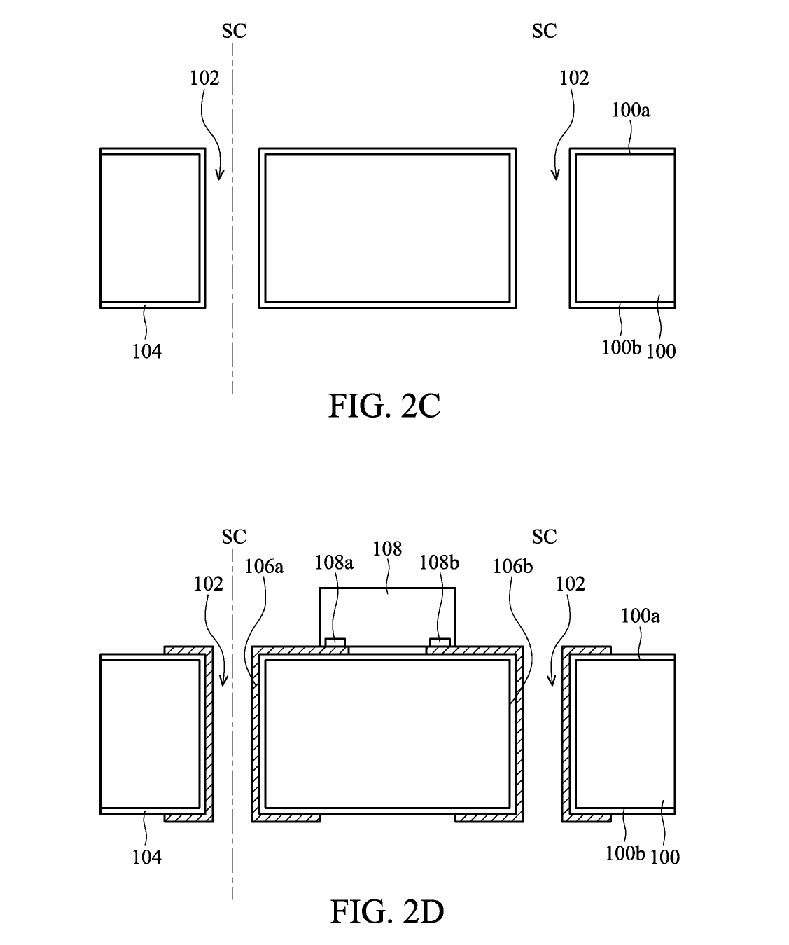

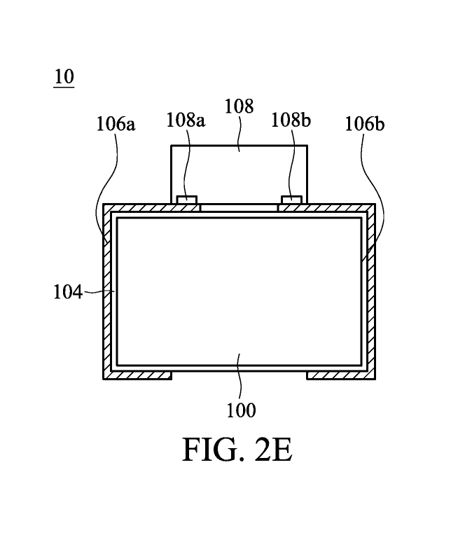

FIGS. 1A-1G are illustrative three-dimensional views showing the steps of forming a chip package according to an embodiment of the present invention. FIGS. 2A-2E are cross-sectional views showing the steps of forming a chip package corresponding to the embodiment shown in FIG. 1. Fabrication methods and structures of a chip package according to an embodiment of the invention will be illustrated with references made to FIGS. 1 and 2.

As shown in FIG. 1A, a carrier wafer 100 is provided, wherein a plurality of predetermined scribe lines SC may be defined. The scribe lines SC define the carrier wafer 100 into a plurality of regions. The carrier wafer 100 has an upper surface 100a and an opposite lower surface 100b. The carrier wafer 100 may comprise, for example, a semiconductor material or a ceramic material. For example, the carrier wafer 100 may be a silicon wafer. Alternatively, the carrier wafer 100 may comprise aluminum oxide or aluminum nitride.

FIG. 1B is an enlarged three-dimensional view showing the region A in FIG. 1A, which is used to illustrate the following fabrication processes of the chip package according to the embodiment. It should be appreciated that the fabrication processes mentioned below are not limited to be performed to the region A. In one embodiment, it is preferable to perform similar or same fabrication processes to all of the regions of the carrier wafer 100. After the carrier wafer is diced along the predetermined scribe lines SC in a following dicing process, a plurality of chip packages having sidewall contacts may be formed.

As shown in FIG. 1B, the scribe lines SC surround a region R in the region A. In the following fabrication processes, a chip and conducting routes will be formed on the region R. The carrier wafer 100 will be diced along the scribe lines SC to separate a plurality of chip packages.

As shown in FIG. 1C, a plurality of through-holes 102 penetrating through the upper surface 100a and the lower surface 100b of the carrier wafer 100 are formed on locations of the predetermined scribe lines SC in the carrier wafer 100. The method for forming the through-holes 102 may comprise, for example, a photolithography and an etching processes. In one embodiment, the through-holes 102 may be formed in a single etching process. In another embodiment, the through-holes 102 are formed stepwise. For example, referring to FIG. 2A, holes 102′ extending from the upper surface 100a toward the lower surface 100b of the carrier wafer 100 are first formed. Then, as shown in FIG. 2B, the carrier wafer 100 is thinned from the opposite lower surface 100b of the carrier wafer 100 by, for example, chemical mechanical polishing (CMP) or grinding, such that the preformed holes 102′ are exposed to form the through-holes 102 penetrating the carrier wafer. After a following dicing process, through-substrate conducting structures become sidewall contacts of the chip package.

As shown in FIGS. 1D and 2C, before a conducting layer is formed on sidewalls of the through-holes 102, an insulating layer 104 may be optionally formed on the sidewalls of the through-holes 102 to prevent short circuiting from occurring between subsequently formed conducting layers. However, it should be appreciated that when the material of the carrier wafer 100 is an insulating material, the forming of the insulating layer 104 may be omitted. The insulating layer 104 not only is formed on the sidewalls of the through-holes 102, but also extends overlying other surfaces of the carrier wafer 100, as shown in FIG. 2C.

The material of the insulating layer 104 may be, for example, an epoxy resin, solder mask material, or other suitable insulating material, such as inorganic materials including silicon oxide, silicon nitride, silicon oxynitride, metal oxide, or combinations thereof, or organic polymer materials including polyimide, butylcyclobutene (BCB, Dow Chemical Co.), parylene, polynaphthalenes, fluorocarbons, or acrylates and so on. The method for forming the insulating layer 104 may comprise a coating method, such as a spin coating, spray coating, or curtain coating method, or other suitable deposition methods, such as a liquid phase deposition, physical vapor deposition, chemical vapor deposition, low pressure chemical vapor deposition, plasma enhanced chemical vapor deposition, rapid thermal chemical vapor deposition, or atmospheric pressure vapor deposition method. In one embodiment, the carrier wafer 100 is a silicon wafer and the insulating layer 104 may be a silicon oxide layer obtained by performing a thermal oxidation process to the silicon wafer.

As shown in FIGS. 1E and 2D, a conducting material layer is formed overlying the carrier wafer 100, which extends on the sidewalls of the through-holes 102. Then, the conducting material layer is patterned into a plurality of conducting layers 106 separated from each other without contacting with the predetermined scribe lines SC. As shown in FIG. 1E, each of the patterned conducting layers 106 in the through-holes 102 merely covers a portion of the sidewall of the through-hole. Each of the patterned conducting layers 106 does not cover the predetermined scribe line SC. Thus, when the carrier wafer 100 is diced to separate the plurality of chip packages in subsequent processes, portions diced by the dicing blade do not comprise the conducting layers. Thus, damage of the dicing blade may be prevented. In addition, what is more important is that the patterned conducting layers 106 will not be drawn during the dicing of the wafer, which effectively prevents peeling of the patterned conducting layers from occurring.

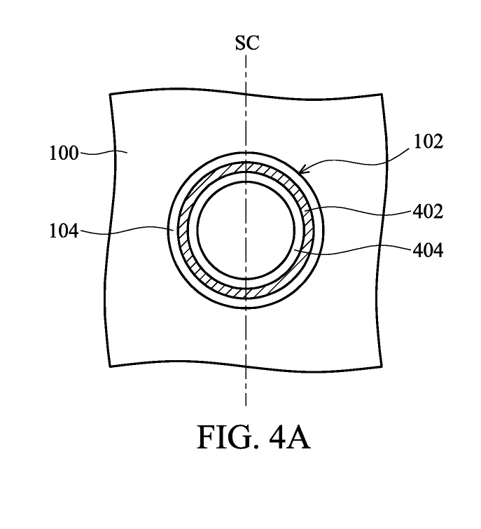

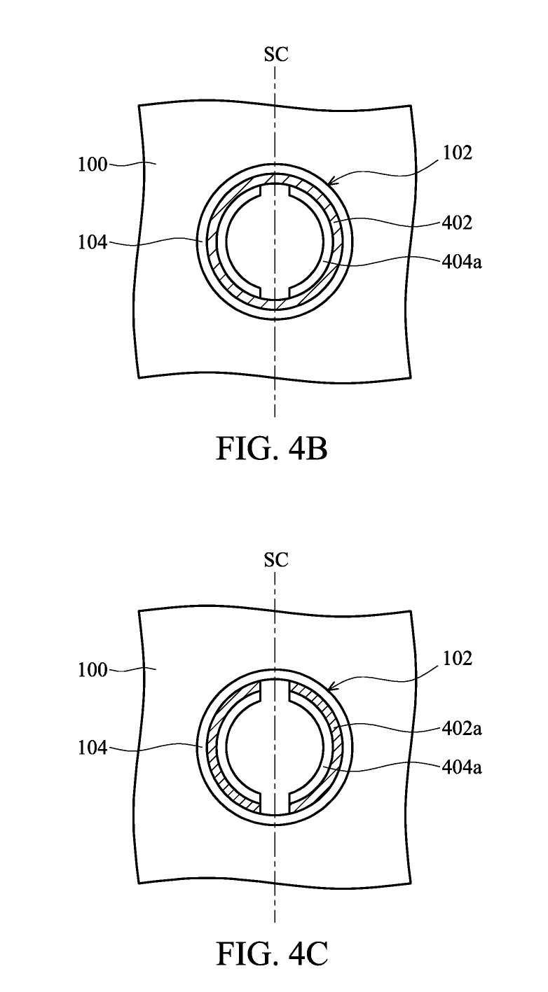

The method for forming the patterned conducting layer in the through-hole will be illustrated with references made to top views shown in FIGS. 4A-4C. However, it should be appreciated that FIGS. 4A-4C are merely used to illustrate one of the methods for forming the patterned conducting layer in the through-hole. The method for forming the patterned conducting layer is not limited thereto.

As shown in FIG. 4A, the insulating layer 104 is first formed on the sidewall of the through-hole 102, and then a seed layer 402 is formed on the insulating layer 104. The seed layer 402 may be formed by, for example, physical vapor deposition. The material of the seed layer 402 may be, for example, a copper. In addition, it is preferable to form a diffusion barrier layer (not shown) between the seed layer 402 and the carrier wafer 100. The material of the diffusion barrier layer may be, for example, a TiW or TiCu material which may prevent a copper from diffusing into the carrier wafer 100 and increase the adhesion between the seed layer 402 and the carrier wafer 100 (or the insulating layer 104).

As shown in FIG. 4A, a photoresist layer 404 is then conformally formed on the seed layer 402. The photoresist layer 404 may be an electroplatable photoresist. Thus, the photoresist layer 404 can be conformally formed on the seed layer 402 by electroplating. For example, the seed layer 402 may be used as an electrode.

Then, as shown in FIG. 4B, the photoresist layer 404 is patterned such that the photoresist layer 404 on regions near the predetermined scribe lines SC is removed and the seed layer 402 near the predetermined scribe lines SC is exposed. Usually, the electroplatable photoresist layer is a negative type resist. Thus, the regions near the predetermined scribe lines SC may be covered by a shield. Then, the exposed photoresist layer 404 is irradiated with a light and hardened. The photoresist layer not irradiated with the light may be removed to form a patterned photoresist layer 404a.

Then, as shown in FIG. 4C, the patterned photoresist layer 404a is used as a mask and an etching process is performed to the seed layer 402. After the exposed seed layer 402 is removed, a patterned seed layer 402a is therefore formed.

Then, the patterned photoresist layer 404a may be removed. The patterned seed layer 402a may be used as an electrode and an electroplating process may be performed to form a conducting material on the patterned seed layer 402a to form the patterned conducting layer, such as the conducting layers 106 shown in FIG. 1E.

It should be appreciated that the seed layer 402 is not only located in the through-hole 102, but also extends overlying the surface of the carrier wafer 100. In this case, the seed layer 402 extending overlying the surface of the carrier wafer 100, may be simultaneously patterned to form desired conducting patterns. Thus, during the forming of the patterned conducting layers 106, a variety of wire layouts may be formed on the carrier wafer 100, such as a redistribution layer, which may be used as a conducting wire of a subsequently disposed chip. As shown in FIG. 2D, when the conducting layers 106, which do not contact with the scribe lines SC, are formed, the conducting wires extending on the surface 100a and/or 100b are also defined. For example, the conducting wires used to electrically connect to a chip or a conducting bump may be defined.

Referring to FIGS. 1F and 2D, a plurality of chips 108 are then provided. Each of the chips 108 has a first electrode 108a and a second electrode 108b. The chips 108 are correspondingly disposed on the region R, respectively. In one embodiment, each of the regions R has at least a chip 108 disposed thereon. The first electrode 108a and the second electrode 108b of the chip 108 are electrically connected to at least two conducting layers in the region R, respectively. For example, as shown in FIGS. 1F and 2D, the first electrode 108a and the second electrode 108b of the chip 108 are electrically connected to a first conducting layer 106a and a second conducting layer 106b of the conducting layers 106, respectively. The chip 108 may be, for example, a light emitting chip. The chip 108 may also be other types of chips, such as an image sensor chip. In one embodiment, a plurality of light emitting chips are disposed on the region R to form, for example, an array of light emitting chips.

Then, the carrier wafer 100 is diced along the predetermined scribe lines SC, as shown in FIG. 1F, to separate a plurality of chip packages. Because the conducting material layer originally formed on the predetermined scribe lines SC has been removed after the patterning process, the conducting material layer will not be cut during the dicing process. Thus, damage of the dicing blade may be prevented. Also, peeling of the patterned conducting layers 106 caused by the draw of the dicing blade can also be prevented, which improves reliability and yield of devices. FIG. 1G is a three-dimensional view showing one of the chip packages 10.

As shown in FIGS. 1G and 2E, the chip package 10 comprises a carrier substrate 100, which is a portion of the carrier wafer 100, and is therefore still designated by reference number 100. The carrier substrate 100 has an upper surface 100a and a lower surface 100b and has a first side surface 100c and a second side surface 100d. The chip 108 is disposed on the carrier substrate 100 and has a first electrode 108a and a second electrode 108b (such as that shown in FIG. 2E). In addition, the through-holes 102 originally formed in the carrier wafer become a plurality of trenches after the dicing process of the carrier wafer, such as the trenches 102a, 102b, 102c, and 102d shown in FIG. 1G.

As shown in FIG. 1G, the chip package 10 of this embodiment comprises a first trench 102a extending from the upper surface 100a toward the lower surface 100b and extending from the first side surface 100c toward an inner portion of the carrier substrate 100. The chip package 10 further comprises a second trench 102b extending from the upper surface 100a toward the lower surface 100b and extending from the second side surface 100d toward the inner portion of the carrier substrate 100.

As shown in FIGS. 1G and 2E, the chip package 10 comprises a first conducting layer 106a which is located on a sidewall of the first trench 102a and is not coplanar with the first side surface 100c and separated from the first side surface 100c by a first minimum distance d1. The first conducting layer 106a further electrically connects the first electrode 108a of the chip 108 as shown in FIG. 2E.

Similarly, the chip package 10 comprises a second conducting layer 106b which is located on a sidewall of the second trench 102b and is not coplanar with the second side surface 100d and separated from the second side surface 100d by a second minimum distance d2. The second conducting layer 106b further electrically connects the second electrode 108b of the chip 108 as shown in FIG. 2E.

In the embodiment shown in FIG. 1G, the conducting layers formed in the trenches may serve as sidewall contacts of the chip package 10. Although four sidewall contacts are formed in this exemplary embodiment, more or fewer sidewall contacts may be formed in another embodiment, depending on desired application. For example, when the chip 108 is a light emitting diode chip, at least two sidewall contacts need to be formed.

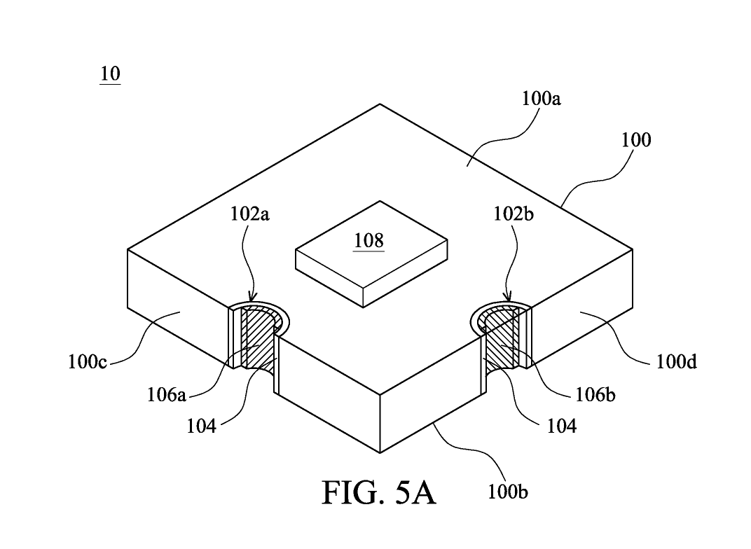

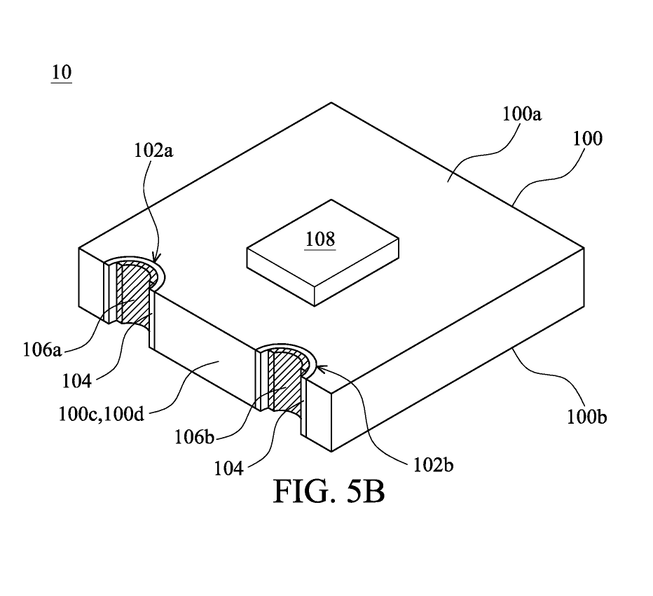

In addition, in the embodiment shown in FIG. 1G, the first side surface 100c is opposite to the second side surface 100d. That is, the first conducting layer 106a electrically connected to the first electrode 108a and located in the first trench 102a is disposed opposite to the second conducting layer 106b electrically connected to the second electrode 108b and located in the second trench 102b. However, embodiments of the invention are not limited thereto. In another embodiment, the first side surface 100c and the second side surface 100d are substantially perpendicular to each other such as that shown in the three-dimensional view in FIG. 5A. In another embodiment, the first side surface 100c and the second side surface 100d are substantially a same side surface such as that shown in the three-dimensional view in FIG. 5B.

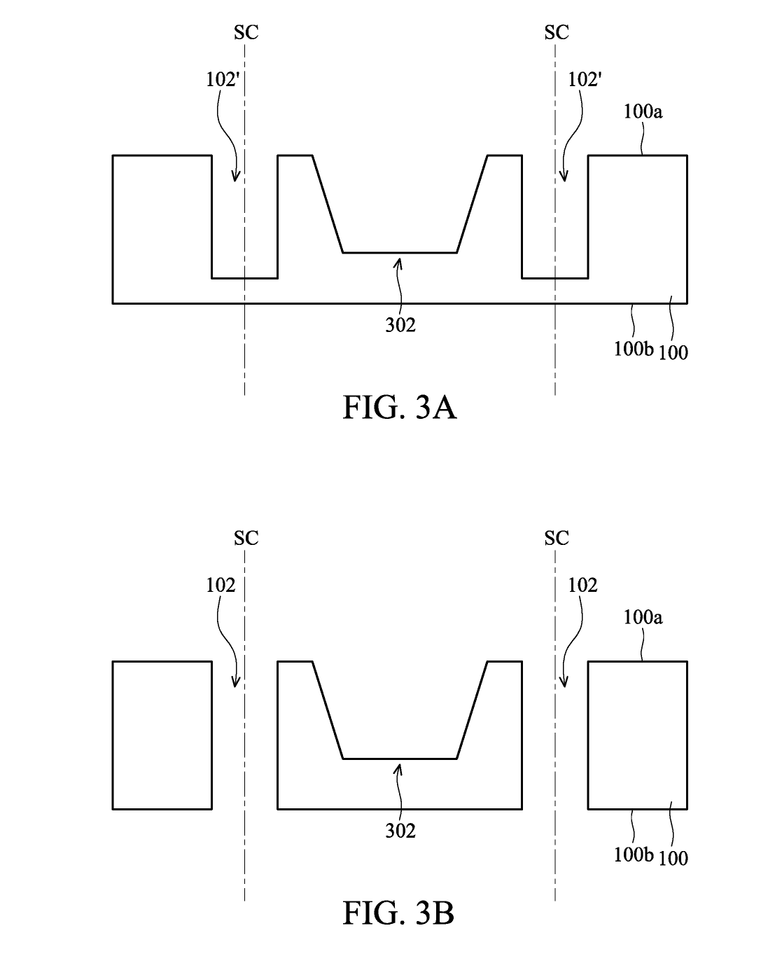

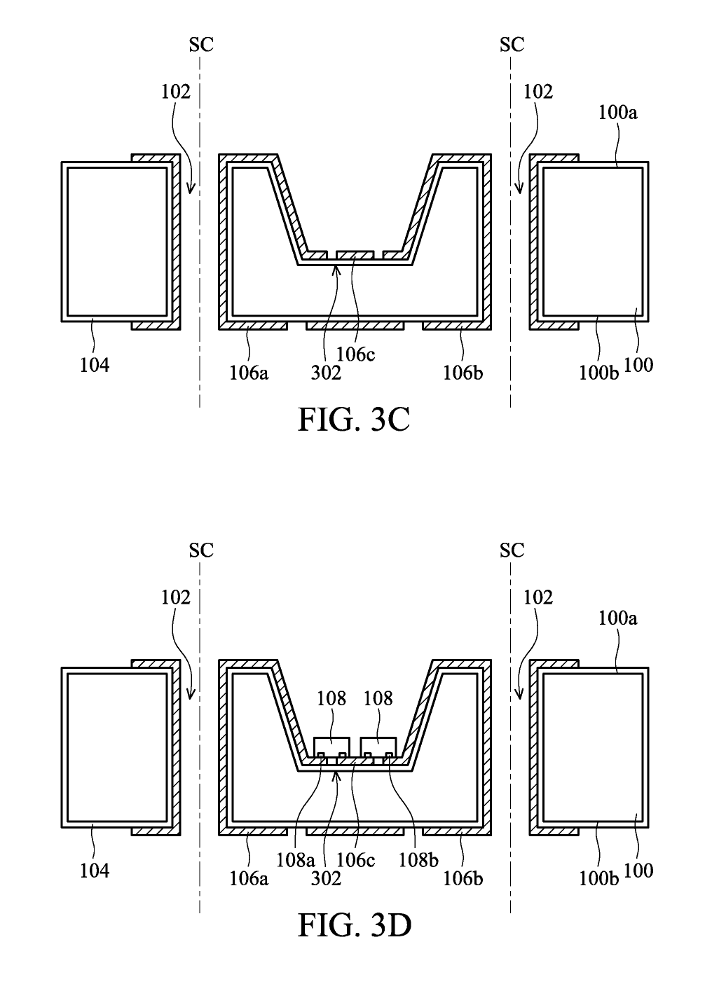

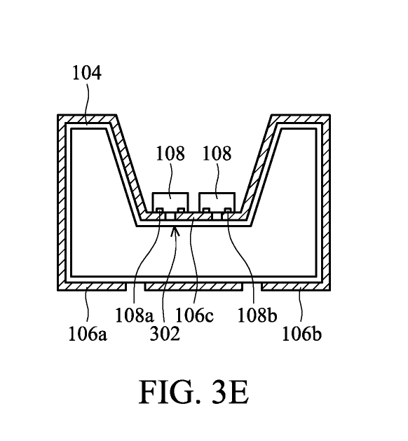

The chip package of the embodiment of the invention may have many other variations. FIGS. 3A-3E are cross-sectional views showing the steps of forming a chip package according to an embodiment of the invention. This embodiment is similar to the embodiment shown in FIGS. 1 and 2. The main difference is that a plurality of recesses 302 are further formed in the carrier wafer 100. As shown in FIG. 3A, the recesses 302 may be formed by a method that is similar to that used to form the holes 102′. In one embodiment, the recesses 302 and the holes 102′ are formed simultaneously.

Then, as shown in FIG. 3B, a similar process, as previously mentioned, may be performed to thin the carrier wafer 100 to form the through-holes 102. As shown in FIG. 3C, the insulating layer 104 may then be optionally formed overlying the carrier wafer 100, and a plurality of patterned conducting layers may be defined such as the conducting layers 106a and 106b. The conducting layers further extend into the recess 302 and are used to form conducting routes with a chip which may be subsequently disposed in the recess.

As shown in FIG. 3D, at least a chip 108 may be disposed in the recess 302. In this embodiment, a plurality of chips 108 are disposed. In this case, the conducting layers 106a and 106b extending on a sidewall of the recess 302 may serve as reflective layers which further improve light-emitting brightness of the chip package.

Then, as shown in FIG. 3E, the carrier wafer is diced along the predetermined scribe lines SC to form a plurality of chip packages. In this embodiment, the conducting layers 106a and 106b “shrink back” and are not coplanar with the side surface of the chip package. Thus, the conducting material layer will not be cut during the dicing process. Thus, damage of the dicing blade may be prevented. Also, peeling of the patterned conducting layer caused by the draw of the dicing blade may be effectively prevented, which improves reliability and yield of devices.

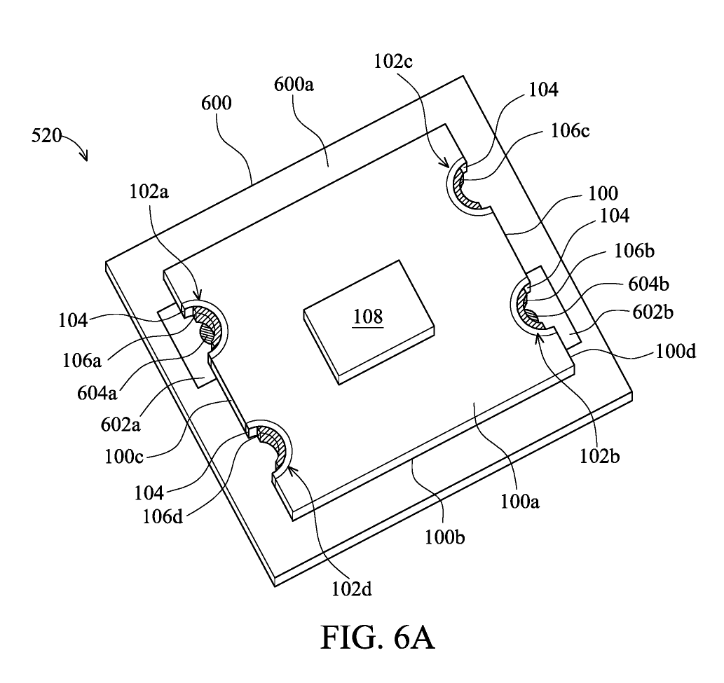

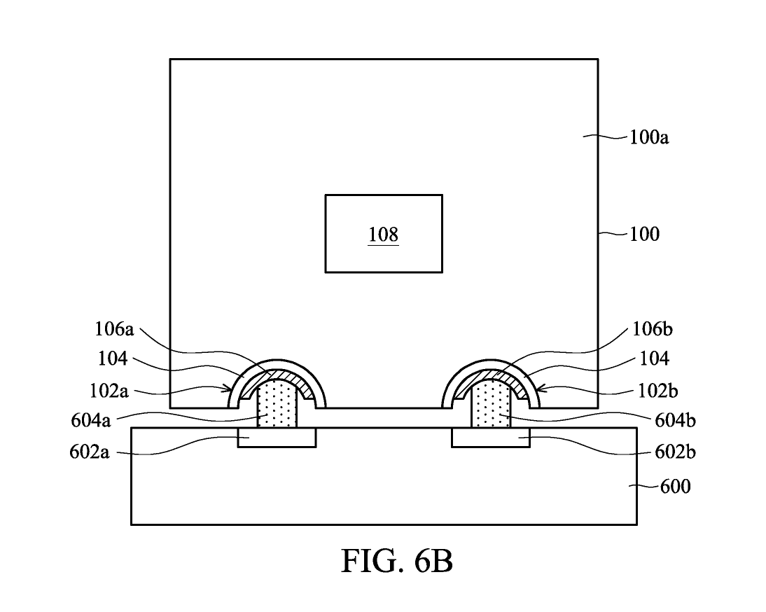

The chip package according to an embodiment of the invention may further be disposed on a circuit board. As shown in FIG. 6A, the chip package may be disposed on a circuit board 600. The circuit board 600 is, for example, a printed circuit board, which may have a first pad 602a and a second pad 602b on its surface 600a. Then, conducting structures 604a and 604b are formed on interfaces between the sidewall contacts (i.e., the conducting layers 106a and 106b) and the first pad 602a and the second pad 602b, respectively. The conducting structures 604a and 604b may be, for example, conductive solders which can not only adhere and fix the patterned conducting layer and the pad, but also form the conducting routes therebetween. Because the conducting structures 604a and 604b are formed on the sidewall of the chip package, it is easier to observe success or failure of the soldering process or the deposition process of the conductor. Thus, process factors during fabrication may be modified and tuned in real time, which may improve process yield. In one embodiment, the packaged chip 108 is a light emitting chip and its light emerging surface may be, for example, its upper surface. In this case, a normal vector of the surface 600a of the circuit board 600 is substantially parallel to a normal vector of the light emerging surface of the chip 108.

The chip package having sidewall contacts according to an embodiment of the invention may also be disposed on a circuit board in another way. As shown in FIG. 6B, the chip package may be disposed on the circuit board 600 in an upright position. The conducting route between the first conducting layer 106a and the first pad 602a may be formed through the conducting structure 604a. Similarly, the conducting route between the second conducting layer 106b and the second pad 602b may be formed through the conducting structure 604b. In one embodiment, the packaged chip 108 is a light emitting chip and its light emerging surface may be, for example, its upper surface. In this case, the normal vector of the surface 600a of the circuit board 600 is substantially perpendicular to the normal vector of the light emerging surface of the chip 108.

The chip package of the embodiments of the invention has many advantageous features. For example, because the through-holes are formed on the scribe lines, used area of the carrier wafer may be significantly reduced. Sidewall contacts may be formed, which may be used in a variety of packages. In addition, because the conducting layer in the through-hole is patterned and does not contact with the scribe line, process yield and reliability of the package may be improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a carrier substrate having an upper surface and an opposite lower surface and having a first side surface and a second side surface;
a chip disposed on the upper surface or the lower surface of the carrier substrate and having a first electrode and a second electrode;
a first trench extending from the upper surface toward the lower surface of the carrier substrate and extending from the first side surface toward an inner portion of the carrier substrate;
a first conducting layer located on a sidewall of the first trench and electrically connected to the first electrode, wherein the first conducting layer is not coplanar with the first side surface and is separated from the first side surface by a first minimum distance;
a second trench extending from the upper surface toward the lower surface of the carrier substrate and extending from the second side surface toward the inner portion of the carrier substrate; and
a second conducting layer located on a sidewall of the second trench and electrically connected to the second electrode, wherein the second conducting layer is not coplanar with the second side surface and is separated from the second side surface by a second minimum distance.

2. The chip package as claimed in claim 1, wherein the first side surface is opposite to the second side surface.

3. The chip package as claimed in claim 1, wherein the first side surface is substantially perpendicular to the second side surface.

4. The chip package as claimed in claim 1, wherein the first side surface and the second side surface are a same side surface.

5. The chip package as claimed in claim 1, further comprising an insulating layer located between the first conducting layer and the carrier substrate.

6. The chip package as claimed in claim 1, further comprising an insulating layer located between the second conducting layer and the carrier substrate.

7. The chip package as claimed in claim 1, further comprising a recess extending from the upper surface toward the lower surface, wherein the chip is disposed on a bottom portion of the recess.

8. The chip package as claimed in claim 1, wherein the chip is a light emitting chip.

9. The chip package as claimed in claim 8, further comprising a circuit board having a first pad and a second pad located on a surface of the circuit board, wherein the carrier substrate is disposed on the circuit board and the first conducting layer and the second conducting layer are electrically connected to the first pad and the second pad, respectively.

10. The chip package as claimed in claim 9, wherein a light emerging surface of the light emitting chip has a normal vector substantially parallel to a normal vector of the surface of the circuit board.

11. The chip package as claimed in claim 9, wherein a light emerging surface of the light emitting chip has a normal vector substantially perpendicular to a normal vector of the surface of the circuit board.

12. A method for forming a chip package, comprising:
providing a carrier wafer comprising a plurality of regions defined by a plurality of predetermined scribe lines;
forming a plurality of through-holes penetrating through an upper surface and an opposite lower surface of the carrier wafer on locations of the predetermined scribe lines;
forming a conducting material layer overlying the carrier wafer, wherein the conducting material layer is extended to overly the sidewalls of the through-holes;
patterning the conducting material layer into a plurality of conducting layers which are separated from each other and do not contact with the predetermined scribe lines;
providing a plurality of chips each having a first electrode and a second electrode;
respectively disposing the chips on the corresponding regions, wherein at least one of the chips is disposed on each of the regions, and the first electrode and the second electrode of each of the chips are electrically connected to two of the conducting layers in the regions where the chips are located, respectively; and
dicing the carrier wafer along the predetermined scribe lines to separate a plurality of chip packages.

13. The method for forming a chip package as claimed in claim 12, wherein the step for forming the through-holes comprises:
forming a plurality of holes which extend from the upper surface toward the lower surface of the carrier wafer on the locations of the predetermined scribe lines; and
thinning the carrier wafer from the lower surface to expose the holes.

14. The method for forming a chip package as claimed in claim 13, further comprising forming a plurality of recesses in the carrier wafer, wherein the recesses extend from the upper surface toward the lower surface, and the chips are correspondingly disposed on bottom portions of the recesses, respectively.

15. The method for forming a chip package as claimed in claim 14, wherein the recesses and the holes are formed simultaneously.

16. The method for forming a chip package as claimed in claim 12, further comprising forming an insulating layer between the conducting layer and the carrier wafer.

17. The method for forming a chip package as claimed in claim 12, wherein the chips comprise a light emitting chip.

18. The method for forming a chip package as claimed in claim 17, further comprising:
providing a circuit board having a first pad and a second pad located on a surface of the circuit board; and
disposing one of the chip packages on the circuit board such that the first electrode and the second electrode of the chip package are electrically connected to the first pad and the second pad, respectively.

19. The method for forming a chip package as claimed in claim 18, wherein a normal vector of the surface of the circuit board is substantially parallel to a normal vector of a light emerging surface of the chip.

20. The method for forming a chip package as claimed in claim 18, wherein a normal vector of the surface of the circuit board is substantially perpendicular to a normal vector of a light emerging surface of the chip.
